(19) United States
(12) Patent Application Publication
(10) Pub. No.: US 2010/0237498 A1
(43) Pub. Date: Sep. 23, 2010

(54) PACKAGE FOR SEMICONDUCTOR DEVICE AND PACKAGING METHOD THEREOF

(75) Inventors: Deok Hoon Kim, Chungcheongbuk-Do (KR); Young Sang Cho, Chungcheongbuk-Do (KR); Hwan Chul Lee, Incheon (KR)

Correspondence Address: HOSOON LEE, 9600 SW OAK ST. SUITE 525, TIGARD, OR, 97223, US

(73) Assignee: OPTOPAC CO., LTD., Chungcheongbuk-Do (KR)

(21) Appl. No.: 12/599,298

(22) PCT Filed: Oct. 28, 2008
(86) PCT No.: PCT/KR2008/006340

§ 371 Date: Nov. 8, 2009

(30) Foreign Application Priority Data
Oct. 29, 2007 (KR) 10-2007-0108830
Oct. 28, 2008 (KR) PCT/KR2008/006340

(51) Int. Cl. H01L 23/488; H01L 21/60

(52) U.S. Cl. 257/738; 438/121; 257/778; 257/E21.511; 257/E23.023

(57) ABSTRACT

A semiconductor device package and a method thereof are able to reliably package a semiconductor device on a substrate without using flux. The semiconductor device package includes a semiconductor device and a substrate reciprocally disposed with respect to the semiconductor device, wherein the substrate includes a side reciprocal to the semiconductor device on which there are formed a plurality of prominences surrounding an accommodation region where the semiconductor device is to be disposed. The method of packaging a semiconductor device includes preparing the semiconductor device, preparing a substrate, forming a plurality of prominences to surround an accommodation region on the substrate where the semiconductor device is to be disposed, dropping the semiconductor device within the accommodation region, and packaging the semiconductor device on the substrate.

### TECHNICAL FIELD

The present invention relates to a semiconductor device package and a method thereof capable of reliably packaging a semiconductor device on a substrate without using flux.

### BACKGROUND ART

General semiconductor devices, i.e., chips, are usually packaged using a package that is referred to as a plastic package where the semiconductor device is completely sealed using a sealant such as epoxy resins. Since, however, in case of an image sensor, light has to reach an image sensing region on a surface of the image sensor in order to sense images, it is impossible to use the general plastic package.

Therefore, a ceramic package having a cover glass has been widely used as a package for the image sensor. This ceramic package is more solid than the plastic package, but it requires higher costs than the plastic package.

For the plastic package and the ceramic package, a wire bonding is used to electrically connect a bonding pad and a terminal of the package. However, nowadays most of electronic equipments including a cellular phone require ‘lightweight’, ‘thin’, ‘short’ and ‘small’ characteristics, but the plastic package or the ceramic package using the wire bonding can not satisfy those requirements. Thus, recently, there is increasing interest in flipchip technology capable of significantly reducing the size of a semiconductor package.

According to a semiconductor packaging method referring to as flipchip, a bump is formed on a pad of a semiconductor device having an integrated circuit, wherein the pad is an electrical terminal formed to connect the semiconductor device with an external device, and the bump is connected with an electrical connector, i.e., a pad, of a substrate, e.g., a printed circuit board (PCB). The bump is formed of various materials and has different bonding schemes according to the materials. Generally, solder using stannum (Sn) as a base is used as the material for forming the bump and the solder is bonded on the pad by raising a temperature up to a level higher than a melting point of the solder.

In a flipchip process using the solder, a material such as flux is coated on a connection element. The flux is used for many purposes. A primary object of using the flux is to remove oxide layers brined on surfaces of a pad of a substrate and a bump of a semiconductor chip, thereby accomplishing a solder bonding. If the oxide layers are undesirably removed, the solder bonding is failed. Another object of using the flux is to seal the connection element during the solder bonding process, thereby preventing the connection element from being exposed to air and thus oxidized by oxygen in the air. Since the flux is tacky, it is able to maintain the location of the semiconductor chip until the solder bonding process is completed after positioning the semiconductor chip on the substrate. If there is no tacky characteristic, during a packaging process, the semiconductor chip may be dislocated and thus the pad is bonded to an undesirable bump adjacent to the target bump, causing electrical defects.

Since, however, the remaining flux causes erosion, a cleaning process for removing the flux residue has to be performed after the solder bonding process is completed. Thus, researches have been conducted for fluxless soldering methods applicable to products that cannot be flushed or products that are weak to contamination due to rosin or resin used as a material for the flux, such as an optical semiconductor device, a surface acoustic wave (SAW) filter and a micro electro mechanical systems (MEMS) device.

In case of the fluxless soldering method, it is important to correctly place a bump of a semiconductor chip on a corresponding pad of a substrate. For this purpose, a method, which respectly forms an embossed pattern and an intagliated pattern on the semiconductor chip and the substrate and interlocks the patterns with each other, is generally used to maintain the exact location of the semiconductor chip. However, an additional process for forming the embossed and intagliated patterns increases manufacturing costs. Furthermore, when high integration is required, it is difficult to provide an area where the embossed and intagliated patterns are formed.

### DISCLOSURE OF INVENTION

### Technical Problem

The present invention provides a semiconductor device package and a method thereof capable of readily and accurately locating a semiconductor device on a substrate using a fluxless soldering technique, thereby simplifying a packaging process of the semiconductor device.

### Technical Solution

In accordance with an exemplary embodiment of the present invention, a semiconductor device package includes a semiconductor device and a substrate reciprocally disposed with respect to the semiconductor device, wherein the substrate includes a side reciprocal to the semiconductor device on which there are formed a plurality of prominences surrounding an accommodation region where the semiconductor device is to be disposed.

The size of the accommodation region may be greater than that of the semiconductor device by approximately 40 μm to approximately 100 μm in one direction.

The semiconductor device may have a polygonal shape and at least one prominence is formed at each of four sides surrounding the semiconductor device.

The prominence may be a solder ball bonded on the substrate or a passive element included in the substrate.

The prominence may be formed to be bonded on a metal line patterned on the substrate.

The semiconductor device may include a plurality of input/output terminals and a plurality of flipchip solder jointers formed on the plurality of input/output terminals, and the substrate may include a patterned metal line and a passivation layer coated on the metal line, wherein the passivation layer has openings in its given portions and the metal line is exposed through the openings to form bump pads where the flipchip solder jointers are bonded.

The height of an exposed upper portion of the bump pad formed in the opening may be less than that of an exposed upper portion of the passivation layer.

The difference between the height of the exposed upper portion of the bump pad formed in the opening and that of the exposed upper portion of the passivation layer may be equal to or greater than 4 μm.

In accordance with another exemplary embodiment of the present invention, a method of packaging a semiconductor device includes: preparing the semiconductor device; preparing a substrate; forming a plurality of prominences to surround an accommodation region on the substrate where the semiconductor device is to be disposed; dropping the semiconductor device within the accommodation region; and packaging the semiconductor device on the substrate.

When forming the prominences, the accommodation region may be defined to have the size greater than that of the semiconductor device by approximately 40 μm to approximately 100 μm in one direction.

The method may further include, after dropping the semiconductor device, vibration the substrate to dispose the semiconductor device within the accommodation region on the substrate.

The preparing of the substrate may include: patterning a metal line on the substrate; forming a passivation layer on the metal line; and removing given portions of the passivation layer to expose the metal line through the removed portions of the passivation layer, thereby firming a plurality of bump pads and a multiplicity of first connection terminals, wherein the prominences are formed by bonding solder balls on the first connection terminals.

The preparing of the substrate may include: patterning a metal line on the substrate; forming a passivation layer on the metal line; and removing given portions of the passivation layer to expose the metal line through the removed portions of the passivation layer, thereby forming a plurality of bump pads and a multiplicity of first and second connection terminals, wherein the prominences are formed by bonding passive elements on the second connection terminals.

The preparing of the semiconductor device may include forming a plurality of input/output terminals and bonding a plurality of flipchip solder jointers on the plurality of input/output terminals; the preparing of the substrate may include forming openings in the passivation layer to form the bump pads; and the dropping of the semiconductor device may be performed by dropping the semiconductor device to place the flipchip solder jointers onto the openings.

During preparing the substrate, an exposed upper portion of the bump pad may be formed to have the height less than that of an exposed upper portion of the passivation layer.

During preparing the substrate, the exposed upper portion of the bump pad and the exposed upper portion of the passivation layer may be formed to have a height difference there between equal to or greater than 4 μm.

During preparing the substrate, the opening may be formed to have the size greater than that of the corresponding flipchip solder jointer of the semiconductor device by more than 10 μm.

The packaging of the semiconductor device on the substrate may include mounting the substrate on which the semiconductor device is disposed into a chamber and exposing the substrate to a formic acid gas.

The packaging of the semiconductor device on the substrate may include: mounting the substrate on which the semiconductor device is disposed into the chamber; supplying the formic acid gas into the chamber; raising an inner temperature of the chamber up to approximately 150° C.; raising the inner temperature of the chamber up to a range of approximately 150° C. to approximately 260° C.; and packaging the semiconductor device on the substrate as exposing the substrate on which the semiconductor device is disposed to the formic acid gas and maintaining the chamber at a peak temperature.

### Advantageous Effects

In accordance with exemplary embodiments of the present invention, a semiconductor device can be correctly located on a substrate although the location accuracy of the semiconductor device is substantially lowered. Furthermore, it is possible to omit a flux coating process and thus a process time for the semiconductor device package is substantially shortened.

A semiconductor packaging process can be conducted without using a high-priced aligning apparatus having high precision, which is used correctly locating the semiconductor device, resulting in improving productivity and reducing the unit cost of production.

### BRIEF DESCRIPTION OF THE DRAWINGS

Exemplary embodiments can be understood in more detail from the following description taken in conjunction with the accompanying drawings, in which:

FIG. 1 is a schematic plan view of a typical semiconductor device;

FIG. 2 is a schematic plan view of a semiconductor device package in accordance with a first embodiment of the present invention;

FIGS. 3 and 4 are schematic cross-sectional views of the semiconductor device package in accordance with the first embodiment of the present invention;

FIG. 5 is a schematic plan view of a semiconductor device package in accordance with a second embodiment of the present invention;

FIGS. 6 and 7 are schematic cross-sectional views of the semiconductor device package in accordance with the second embodiment of the present invention;

FIG. 8 is a flowchart illustrating a method of packaging a semiconductor device in accordance with the present invention; and

FIG. 9 is an X-ray analysis image of a semiconductor device package in accordance with the present invention.

### BEST MODE FOR CARRYING OUT THE INVENTION

Hereinafter, specific embodiments of the present invention will be described in detail with reference to the accompanying drawings.

The present invention may, however, be embodied in different forms and should not be construed as limited to the embodiments set forth herein. Rather, these embodiments are provided so that this disclosure will be thorough and complete, and will fully convey the scope of the present invention to those skilled in the art.

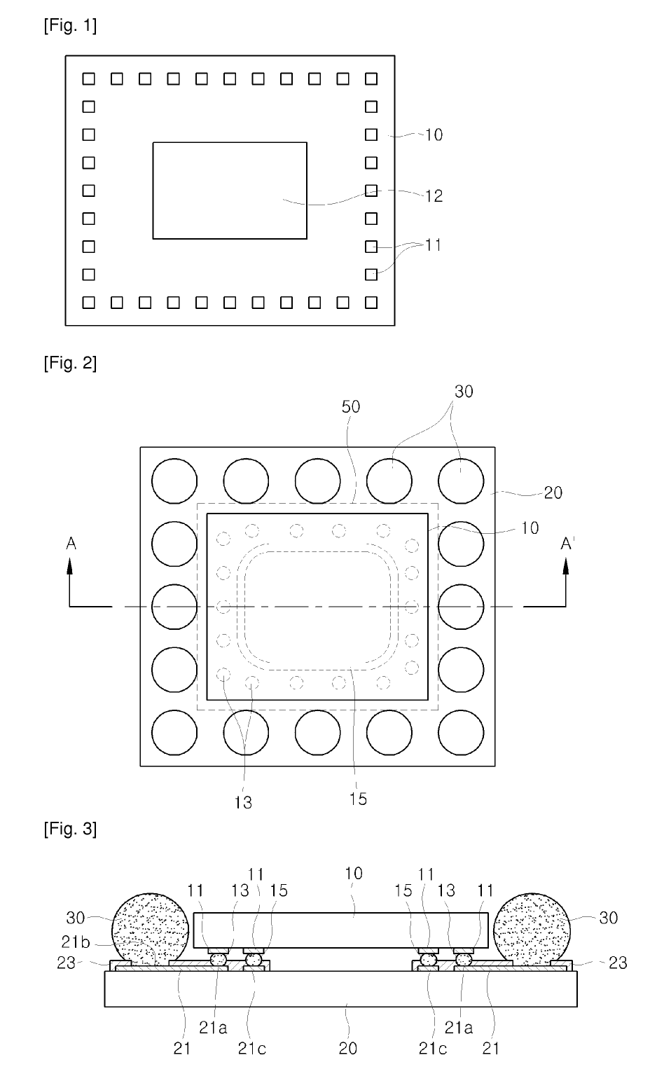

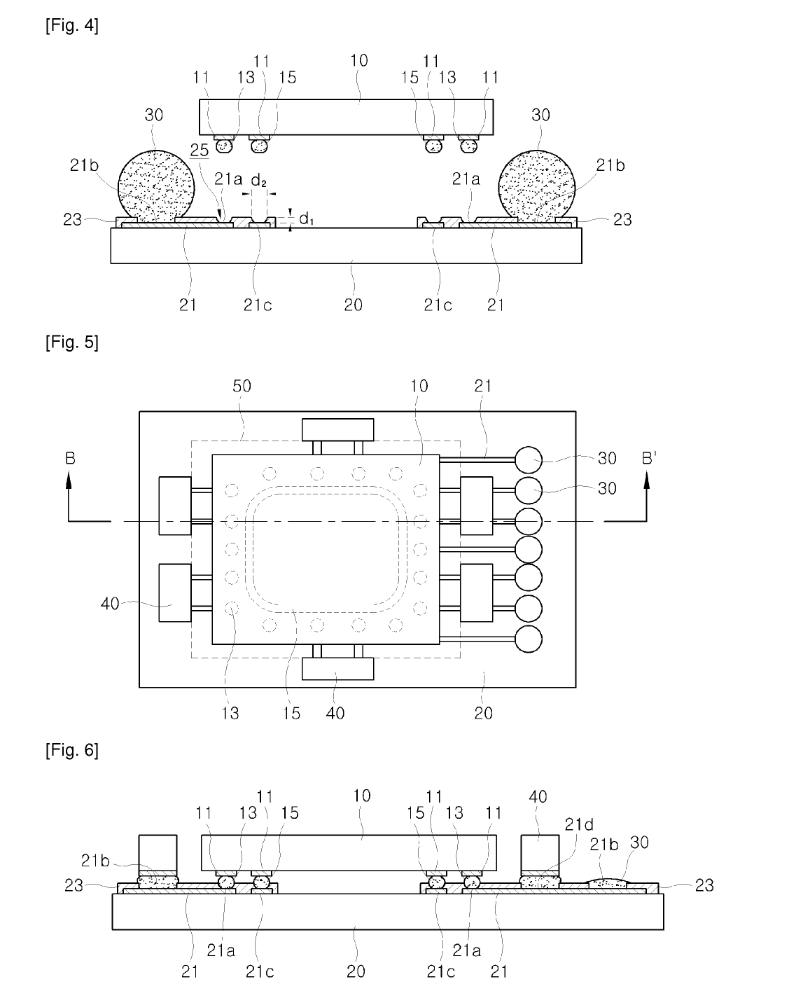

FIG. 1 is a schematic plan view of a typical semiconductor device and FIG. 2 is a schematic plan view of a semiconductor device package in accordance with a first embodiment of the present invention. FIGS. 3 and 4 are schematic cross-sectional views of the semiconductor device package taken along a line A-A′ of FIG. 2.

As shown in drawings, the semiconductor device package in accordance with the present invention includes a semiconductor device 10 and a substrate 20 reciprocally disposed with respect to the semiconductor device 10.

As described in FIG. 1, the semiconductor device 10 may be any device that includes an integrated circuit disposed at a central portion 12 thereof to perform memory and operating functions and a plurality of input/output (I/O) terminals 11 formed at a peripheral portion thereof to supply power or transmit electrical signals. In the following description, the present invention will be explained with respect to an image sensor as the semiconductor device 10.

A plurality of flipchip solder jointers 13 are bonded on the I/O terminals 11.

The flipchip solder jointers 13 electrically connect the semiconductor device 10 with the substrate 20 and may include solder bumps, but they are not limited thereto. The flipchip solder jointer 13 may include two conductive elements or an alloy of two or more conductive elements. The conductive elements may construct an alloy or a structure formed by stacking two or more layers.

The semiconductor device package may further include a sealing ring 15 for sealing the central portion 12 of the semiconductor device 10. The sealing ring 15 may have any shape capable of packaging the central portion 12. For example, the sealing ring 15 may be a closed loop type sealing ring or an unclosed loop type sealing ring having a given width and length and an airway. Furthermore, the sealing ring 15 may be constructed with an unclosed loop type main sealing ring having a given width and one or two auxiliary sealing rings having a width around an unclosed portion of the main sealing ring. In the embodiments of the present invention, the closed loop type sealing ring is adopted.

The substrate 20 may be any type of substrates. However, for the image sensor exemplarily adopted in these embodiments of the present invention, a material having transparent characteristics, e.g., a glass substrate, is used.

The substrate 20 includes a central region corresponding to an accommodation region 50 where the semiconductor device 10 is to be disposed and a metal line 21 patterned around the accommodation region 50. A passivation layer 23 for insulation is formed on the metal line 21. Openings are brined at some portions of the passivation layer 23 to expose the metal line 21 therethrough, thereby forming terminals for connecting, the semiconductor device 10 and external devices. Then there are formed at the terminals bump pads 21a where the flipchip solder jointers 13 bonded on the semiconductor device 10 are bonded, first connection terminals 21b where solder balls 30 are bonded, and a sealing ring pad 21c where the sealing ring 15 is bonded.

The first connection terminals 21b are formed at a region surrounding the accommodation region 50. Thus, as a prominence structure is formed due to the solder balls 30 by bonding the solder balls 30 to the first connection terminals 21b, it is preferable that the accommodation region 50 is surrounded by the solder balls 30. For instance, if the semiconductor device 10 and the accommodation region 50 have a rectangular shape, one or more solder balls are desirably disposed at each of four sides surrounding the semiconductor device 10. Of course, the present invention is not limited thereto. That is, when the semiconductor device has other polygonal shapes, any arrangement may be acceptable if one or more solder balls are disposed at each side.

The size of the accommodation region 50 surrounded by the solder balls 33 may be greater than that of the semiconductor device 10 packaged on the region 50 by approximately 40 μm to approximately 100 μm in one direction. When locating the semiconductor device 10 on the substrate 20, if the accommodation region 50 is smaller than the above size, the solder balls 30 may physically get contact with sides of the semiconductor device 10 after the packaging and thus electrical problems may be caused in the semiconductor device 10. On the other hand, if the accommodation region 50 is greater than the above size, a margin where the semiconductor device 10 is movable within the prominence structure formed by the solder balls 30 becomes large and thus the flipchip solder jointers 13 on the semiconductor device 10 may be bonded on other terminals adjacent to target terminals on the substrate 20, which increases manufacturing defects.

The accommodation region 50 is not limited to a region defined by the solder balls 30 and may be defined by any components capable of surrounding the accommodation region 50 so that the semiconductor device 10 is packaged on the substrate 20 without dislocation. For example, the prominence structure may be formed by passive elements such as capacitors embedded on the substrate 20.

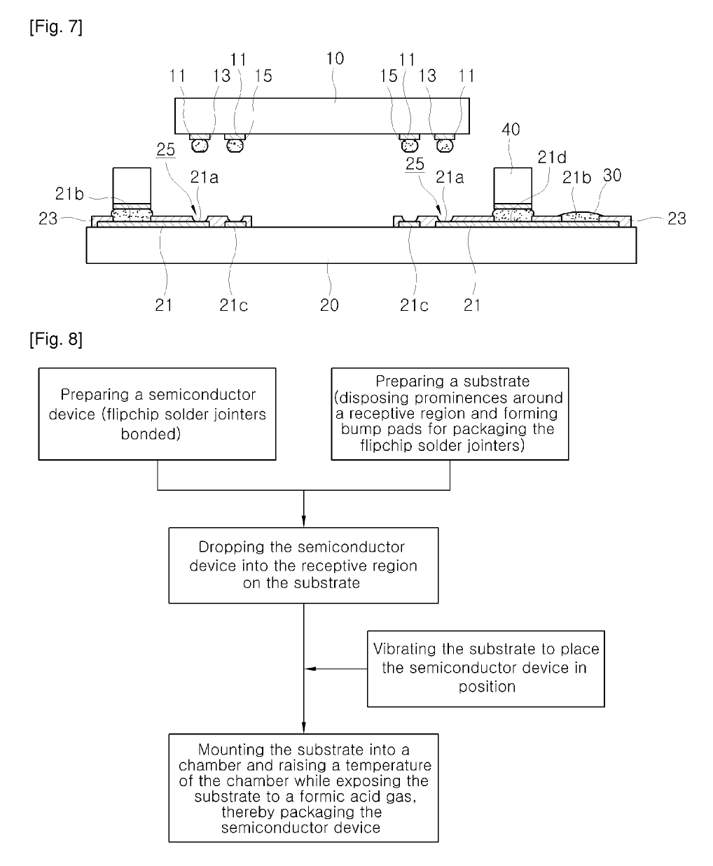

FIG. 5 is a schematic plan view of a semiconductor device package in accordance with a second embodiment of the present invention. FIGS. 6 and 7 are schematic cross-sectional views of the semiconductor device package taken along a line B-B′ of FIG. 5.

As shown in figures, the second embodiment of the present invention provides capacitors 40 that serve as a frame surrounding an accommodation region 50 where a semiconductor device 10 is disposed. A capacitor is usually used to reduce noises.

A substrate 20 includes a central region corresponding to an accommodation region 50 where the semiconductor device 10 is disposed and a metal line 21 is patterned around the accommodation region 50. A passivation layer 23 is formed on the metal line 21. Openings are formed at some portions of the passivation layer 23 to expose the metal line 21 therethrough, thereby forming various terminals. These terminals form second connection terminals 21d where the capacitors 40 are bonded as well as forming bump pads 21a, first connection terminals 21b and a sealing ring pad 21c.

The second connection terminals 21d are disposed at a region surrounding the accommodation region 50. Thus, as a prominence structure is formed by bonding the capacitors 40 to the second connection terminals 21d, it is preferable that the accommodation region 50 is surrounded by the capacitors 40. Like the solder balls 30, the capacitors 40 serve as a frame surrounding the accommodation region 50. Therefore, the size of the accommodation region 50 defined by the capacitors 40 and the location and the number of the capacitors 40 are substantially the same as those of the first embodiment illustrated in FIG. 2.

The bump pads 21a defined by forming openings in the passivation layer 23 is formed to have the height of its exposed upper portion less than that of an exposed upper portion of the passivation layer 23 since cave-in shape openings are made by the height difference between the bump pads 21a and the passivation layer 23 at the location where the bump pads 21a are formed. Hereinafter, the openings formed in the passivation layer 23 to define the bump pads will be referred to as concavities 25. By forming the concavities 25, there is secured an effect of the flipchip solder jointers 13 being confined in the concavities 25 when disposing the semiconductor device 10 on the substrate 20, so that the semiconductor device 10 is placed at a right position on the substrate 20 or prevented from being dislocated after being placed in position. The depth of the concavities 25, d1, i.e., the height difference between the exposed upper portion of the bump pad 21a and that of the passivation layer 23, may be preferably equal to or greater than 4 μm so that the flipchip solder jointers 13 are placed at right positions of the concavities 25 and maintain the placement. The concavities 25 are formed to have the maximal depth dl that is equal to or less than the height of the passivation layer 23.

The width d2 of the concavities 25 may be greater than that of the flipchip solder jointers 13 bonded on the semiconductor device 10 by 10 μm or more. Thus, by forming the concavities 25 to have the size greater than that of the flipchip solder jointers 13, when dropping the semiconductor device 10 into the accommodation region 50 defined by the capacitors 40, the flipchip solder jointers 13 of the semiconductor device 10 may be readily placed at the concavities 25 without dislocation. The maximal size of the concavities 25 may be in a range where interference between a certain concavity and it adjacent concavity does not occur.

Hereinafter, a method of packaging the semiconductor device having a configuration described above will be explained in detail with reference to the accompanying drawings.

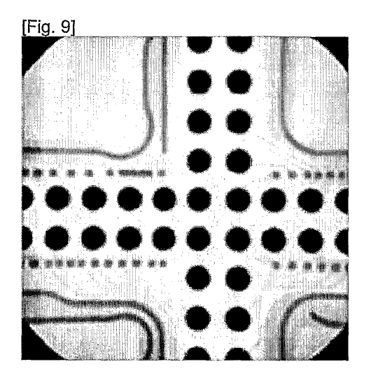

FIG. 8 is a flowchart illustrating a method of packaging a semiconductor device in accordance with an embodiment of the present invention.

Referring to FIG. 8, the semiconductor device packaging method includes preparing a semiconductor device 10, preparing a substrate 20, forming prominences on the substrate 20 to surround an accommodation region 50 where the semiconductor device 10 is to be placed, dropping the semiconductor device 10 into the accommodation region 50, mounting the substrate 20 where the semiconductor device 10 is disposed into a chamber, and exposing the substrate 20 to a formic acid gas so as to packaging the semiconductor device 10 onto the substrate 20.

The step of preparing the semiconductor device 10 starts from fabricating a semiconductor wafer including a plurality of semiconductor devices. A chip maker fabricates and supplies the semiconductor wafer in a fab-out stage. Then, the semiconductor wafer requires several post processes after the fab-out stage so as to be applied to the inventive semiconductor device package. Herein, for convenience of description, only the post processes will be explained.

In the post processes, a plurality of I/O terminals 11 are formed according to the configuration of the semiconductor device 10 and then a plurality of flipchip solder jointers 13 are bonded onto the I/O terminals 11. At this time, a sealing ring 15 may be bonded onto I/O terminals where the flipchip solder jointers 13 are not bonded.

The step of preparing the substrate 20 is performed by designating at least one unit substrate that is to be electrically connected to the semiconductor device 10, forming at least one metal layer on a top surface of the unit substrate, patterning the metal layer to form a metal line 21, forming a passivation layer 23 to protect the metal line 21, and patterning the passivation layer 23 to expose some portions of the metal line 21 to thereby form bump pads 21a where the flipchip solder jointers 13 are to be bonded and first connection terminals 21b for electrically connecting a package with an external circuit board. In this step, a sealing ring pad 21c to be bonded to the sealing ring 15 may be further formed.

In order to form the bump pads 21a, concavities 25 are formed to allow the bump pads 21a to have the height of its exposed upper portion less than that of an exposed upper portion of the passivation layer 23. preferably, the height difference between a top surface of the bump pads 21a and that of the passivation layer 23 may be equal to or greater than 4 μm and the width of the concavities 25 may be greater than that of corresponding flipchip solder jointers 13 of the semiconductor device 10 by 10 μm or more.

The step of forming the prominence structure on the substrate 20 is performed by placing the first connection terminals 21b to surround the accommodation region 50 and bonding solder balls 30 to the first connection terminals 21b. Herein, the size of the accommodation region 50 may be greater than that of the semiconductor device 10 by approximately 40 μm to approximately 100 μm in one direction as described above.

In addition to forming the prominence structure using the solder balls 30, the prominence structure may be formed by further forming second connection terminals 21d through which passive elements such as capacitors 40 are bonded onto the metal line 21 in the process of preparing the substrate 20 and bonding the capacitors 40 to the second connection terminals 21d. The capacitors 40 are disposed to surround the accommodation region 50 like the solder balls 30.

The step of dropping the semiconductor device 10 represents a process of placing the semiconductor device 10 in the accommodation region 50 formed on the substrate 20. In this step, the semiconductor device 10 is dropped within the accommodation region 50, i.e., a frame constructed by, e.g., the solder balls 30 or the capacitors 40 surrounding the accommodation region 50. If the frame is constructed by the solder balls 30 or the capacitors 40, it is possible to drop the semiconductor device 10 into the accommodation region 50 without dislocation in the state of not requiring high accuracy for placing the semiconductor device 10 in position. Then, if the semiconductor device 10 is disposed within the accommodation region 50, the flipchip solder jointers 13 bonded onto the semiconductor device 10 are safely placed onto the concavities 25 formed on the substrate 20. The semiconductor device 10 placed onto the substrate 20 is in position by the prominence structure formed by the solder balls 30 or the capacitors 40 and maintains its position.

In accordance with the present invention, an apparatus used for dropping the semiconductor device 10 does not require supersonic waves, flux coating or thermal bonding functions unlike a conventional flipchip bonding apparatus. The inventive apparatus picks up and reverses the semiconductor device and drops it into the accommodation region formed by the prominence structure in high speed. This apparatus may include a pick & drop apparatus and is improved as much as more than three times in costs and productivity compared to the conventional flipchip bonding apparatus.

In accordance with another embodiment of the present invention, for the case that the flipchip solder jointers 13 of the semiconductor device 10 are not exactly placed in the concavities 25, the semiconductor device packaging method further includes vibration the substrate 20 after the semiconductor device 10 is dropped into the accommodation region 50 to thereby place the semiconductor device 10 in position.

By vibration the substrate 20 on which the semiconductor device 10 is slightly dislocated, the flipchip solder jointers 13 of the semiconductor device 10 become fallen into the concavities 25 where the bump pads 21a corresponding to the flipchip solder jointers 13 are disposed. The vibration process is performed in the same apparatus where the semiconductor device 10 is dropped and which embeds a vibration means therein or in a vibration apparatus separately prepared.

The extent of vibration may be as much as the semiconductor device 10 not being jumped out of the prominence structure and the flipchip solder jointers 13 not being deviated from the concavities 25 after being disposed.

The step of packaging the semiconductor device 10 on the substrate 20 is performed through a soldering method that uses a formic acid gas without using the flux. The substrate 20 where the semiconductor device 10 is disposed is mounted into a vacuum reflow chamber. Then, a temperature of the chamber is raised and the formic acid gas is supplied into the chamber, so that the flipchip solder jointers 13 and the sealing ring 15 are bonded.

The formic acid used in the present invention has a boiling point of 100.5° C., a melting point of 8.4° C., a specific gravity of 1.22 and an irritating scent. The formic acid is colorless and it in a liquid state at room temperature and water-soluble. The formic acid reacts with an oxide layer at a reflow temperature as described in a following chemical formula 1, thereby forming a metal compound. Then, the metal compound is deoxidized as described in a following chemical formula 2 to remove the oxide layer on a surface of metal.

MO+2HCOOH=M(COOH)₂+H₂O [Formula 1]

The above reaction is performed in a temperature range of 150° C. to 200° C.

M(COOH)₂=M+CO₂+H₂

H₂+MO=M+H₂O [Formula 2]

The above reaction is performed in a temperature range of greater than 200° C.

In the above chemical formulas 1 and 2, M means metal.

The process of packaging the semiconductor device 10 on the substrate 20 is explained in detail hereinafter.

First of all, the substrate 20 on which the semiconductor device 10 is disposed is mounted into a chamber. The chamber is a vacuum reflow chamber. For example, the vacuum reflow chamber is an apparatus such as a rapid thermal process apparatus generally used in a semiconductor fabricating process. The vacuum reflow chamber includes a halogen lamp embedded under a substrate and is able to precisely adjust a temperature in high speed in a vacuum as measuring a temperature of a sample with a temperature sensor. The gas supply into the vacuum reflow chamber can be precisely adjusted using a mass flow controller (MFC).

After the substrate 20 is mounted into the vacuum reflow chamber, a formic acid gas is supplied into the vacuum reflow chamber. A nitrogen gas is used as a carrier gas in order to supply the formic acid that is in liquid state at room temperature into the vacuum reflow chamber. Then the inner temperature of the chamber is raised up to 150° C. At this time, to prevent the substrate 20 and the semiconductor device 10 from being thermally damaged, it is preferable to raise the inner temperature by 1° C. per second and maintain the inner pressure as 5 mTorr.

After the inner temperature of the chamber is raised up to 150° C., the nitrogen gas of 5 SLM (standard liter per minute) and the formic acid gas of 0.5 SLM are supplied to the chamber and the inner temperature of the chamber is raised up to 150° C. to 260° C. At this time, the inner temperature is raised by 0.5° C. per second. As a result, the reaction described in the above chemical formulas 1 and 2 are achieved. The metal compound is formed according to the formula 1 until the inner temperature of the chamber reaches exactly 200° C. and, then, the deoxidation of the metal compound is performed according to the formula 2 from a temperature level of higher than 200° C. so as to remove the oxide layer.

For example, the peak temperature of the chamber maintains about 260° C. for 30 seconds. As the metal compound is continuously deoxidized according to the formula 2, the flipchip solder jointers 13 and the sealing ring 15 are bonded, so that the semi-conductor device 10 is bonded onto the substrate 10. At this time, although the flipchip solder jointers 13 and the sealing ring 15 are slightly dislocated with the corresponding bump pads 21a and the sealing pad 21c, once the bonding proceeds, the flipchip solder jointers 13 and the sealing ring 15 are pulled toward the bump pads 21a and the sealing pad 21c by the surface tension, so that the semiconductor device 10 is packaged into the right position on the substrate 20.

The bonding temperature of the solder jointers and the sealing ring may be changed in response to the variation of compounds forming the solder jointers and the sealing ring.

After the semiconductor device 10 is packaged on the substrate 10, the gas remaining within the vacuum reflow chamber is exhausted to the outside.

In order to verify the effectiveness of the method of packaging the semiconductor device in accordance with the present invention, some experiments were executed.

Three times of experiments were executed according to the inventive semiconductor device packaging method. The results show that a ratio of the flipchip solder jointers of the semiconductor device that are correctly jointed onto total 1315 unit substrates on the substrate was more than 95%.

FIG. 9 is an X-ray analysis image of a semiconductor device package in accordance with the present invention.

As can be seen from FIG. 9, it is verified that the semiconductor device is exactly bonded in position and there are very few voids within the flipchip solder jointers and the sealing ring. In the conventional soldering products using the flux, it is difficult to control the generation of voids according to reflow processing requirements, the amount of plug used, or the extent of oxidation of bump pads and connection terminals. If the number or size of voids exceeds a given level, it gives a very bad effect onto the reliability of the products. However, in accordance with the present invention, it is possible to fabricate products having very few voids or no void.

Although the fluxless soldering method using the image sensor, the glass substrate and the formic acid gas has been described with reference to the specific embodiments, they are not limited thereto. Therefore, it will be readily understood by those skilled in the art that various modifications and changes can be made thereto without departing from the spirit and scope of the present invention defined by the appended claims.

1-20. (canceled)

21. A semiconductor device package, comprising:
a semiconductor device; and
a substrate reciprocally disposed with respect to the semiconductor device,
wherein the substrate includes a side reciprocal to the semiconductor device on which there are formed a plurality of prominences surrounding an accommodation region where the semiconductor device is to be disposed.

22. The semiconductor device package of claim 21, wherein the size of the accommodation region is greater than that of the semiconductor device by approximately 40 μm to approximately 100 μm in one direction.

23. The semiconductor device package of claim 21, wherein the semiconductor device has a polygonal shape and at least one prominence is formed at each of four sides surrounding the semiconductor device.

24. The semiconductor device package of claim 21, wherein the prominence is a solder ball bonded on the substrate.

25. The semiconductor device package of claim 21, wherein the prominence is a passive element included in the substrate.

26. The semiconductor device package of claim 24, wherein the prominence is formed to be bonded on a metal line patterned on the substrate.

27. The semiconductor device package of claim 25, wherein the prominence is formed to be bonded on a metal line patterned on the substrate.

28. The semiconductor device package of claim 21, wherein the semiconductor device comprises a plurality of input/output terminals and a plurality of flipchip solder jointers formed on the plurality of input/output terminals, and the substrate comprises a patterned metal line and a passivation layer coated on the metal line, wherein the passivation layer has openings in its given portions and the metal line is exposed through the openings to form bump pads where the flipchip solder jointers are bonded.

29. The semiconductor device package of claim 28, wherein the height of an exposed upper portion of the bump pad formed in the opening is less than that of an exposed upper portion of the passivation layer.

30. The semiconductor device package of claim 29, wherein the difference between the height of the exposed upper portion of the bump pad formed in the opening and that of the exposed upper portion of the passivation layer is equal to or greater than 4 μm.

31. A method of packaging a semiconductor device, the method comprising:
preparing the semiconductor device;
preparing a substrate;
forming a plurality of prominences to surround an accommodation region on the substrate where the semiconductor device is to be disposed;
dropping the semiconductor device within the accommodation region; and
packaging the semiconductor device on the substrate.

32. The method of claim 31, wherein, when forming the prominences, the accommodation region is defined to have the size greater than that of the semiconductor device by approximately 40 μm to approximately 100 μm in one direction.

33. The method of claim 31, further comprising, after dropping the semiconductor device, vibration the substrate to dispose the semiconductor device within the accommodation region on the substrate.

34. The method of claim 31, wherein preparing the substrate comprises:
patterning a metal line on the substrate;
forming a passivation layer on the metal line; and
removing given portions of the passivation layer to expose the metal line through the removed portions of the passivation layer, thereby forming a plurality of bump pads and a multiplicity of first connection terminals, wherein the prominences are formed by bonding solder balls on the first connection terminals.

35. The method of claim 34, wherein preparing the semiconductor device comprises:
forming a plurality of input/output terminals and bonding a plurality of flipchip solder jointers on the plurality of input/output terminals;
preparing the substrate comprises forming openings in the passivation layer to form the bump pads;
and dropping the semiconductor device is performed by dropping the semiconductor device to place the flipchip solder jointers onto the openings.

36. The method of claim 35, wherein, during preparing the substrate, an exposed upper portion of the bump pad is formed to have the height less than that of an exposed upper portion of the passivation layer.

37. The method of claim 36, wherein, during preparing the substrate, the exposed upper portion of the bump pad and the exposed upper portion of the passivation layer are formed to have a height difference there between equal to or greater than 4 μm.

38. The method of claim 35, wherein, during preparing the substrate, the opening is formed to have the size greater than that of the corresponding flipchip solder jointer of the semiconductor device by more than 10 μm.

39. The method of claim 31, wherein preparing the substrate comprises:
patterning a metal line on the substrate;
forming a passivation layer on the metal line; and
removing given portions of the passivation layer to expose the metal line through the removed portions or the passivation layer, thereby forming a plurality of bump pads and a multiplicity of first and second connection terminals, wherein the prominences are formed by bonding passive elements on the second connection terminals.

40. The method of claim 39, wherein preparing the semiconductor device comprises:
forming a plurality of input/output terminals and bonding a plurality of flipchip solder jointers on the plurality of input/output terminals;
preparing the substrate comprises forming openings in the passivation layer to form the bump pads; and
dropping the semiconductor device is performed by dropping the semiconductor device to place the flipchip solder jointers onto the openings.

41. The method of claim 40, wherein, during preparing the substrate, an exposed upper portion of the bump pad is formed to have the height less than that of an exposed upper portion of the passivation layer.

42. The method of claim 41, wherein, during preparing the substrate, the exposed upper portion of the bump pad and the exposed upper portion of the passivation layer are formed to have a height difference there between equal to or greater than 4 μm.

43. The method of claim 40, wherein, during preparing the substrate, the opening is formed to have the size greater than that of the corresponding flipchip solder jointer of the semiconductor device by more than 10 μm.

44. The method of claim 31, wherein packaging the semiconductor device on the substrate comprises mounting the substrate on which the semiconductor device is disposed into a chamber and exposing the substrate to a formic acid gas.

45. The method of claim 44, wherein packaging the semiconductor device on the substrate comprises:
mounting the substrate on which the semiconductor device is disposed into the chamber;
supplying the formic acid gas into the chamber;
raising an inner temperature of the chamber up to approximately 150° C.;
raising the inner temperature of the chamber up to a range of approximately 150° C. to approximately 260° C.; and
packaging the semiconductor device on the substrate as exposing the substrate on which the semiconductor device is disposed to the formic acid gas and maintaining the chamber at a peak temperature.
